(19) United States
(12) Patent Application Publication
(10) Pub. No.: US 2005/0088060 A1
(43) Pub. Date: Apr. 28, 2005

(54) Compact electronic component including piezo-electric resonator mounted by face-down bonding with improved reliability

(75) Inventors: Eiju Komuro, Tokyo (JP); Toshiyuki Nagatsuka, Tokyo (JP); Tsutomu Yasui, Tokyo (JP)

Correspondence Address: MCGINN & GIBB, PLLC, 8321 OLD COURTHOUSE ROAD, SUITE 200, VIENNA, VA, 22182-3817, US

(73) Assignee: TDK Corporation, Tokyo (JP)

(21) Appl. No.: 10/806,469

(22) Filed: Mar. 23, 2004

(30) Foreign Application Priority Data
Oct. 22, 2003 (JP) 2003-361568

(51) Int. Cl. H01L 41/053

(52) U.S. Cl. 310/344

(57) ABSTRACT

In an electronic component having a piezo-electric resonator 10 formed on an element substrate and obtaining a signal having a predetermined resonant frequency by a bulk wave propagating through a piezo-electric film, a packaging substrate 19 on which the piezo-electric resonator 10 is mounted by face-down bonding through bumps 18, and a lid 21 fixed on the packaging substrate 19 and sealing the piezo-electric resonator 10, a distance between a surface of the piezo-electric resonator 10 facing said packaging substrate 19 and a surface of the packaging substrate 19 facing the piezo-electric resonator 10 is not larger than 100 μm. A maximum diameter of the bump 18 is not larger than 150 μm, when the bump 18 is connected to the packaging substrate 19. A distance between a surface of the piezo-electric resonator 10 facing the lid 21 and a surface of the lid 21 facing the piezo-electric resonator 10 is not larger than 150 μm.

### BACKGROUND OF THE INVENTION

The present invention relates to an electronic component, particularly to the electronic component which uses a piezo-electric resonator utilizing a bulk wave propagating through a piezo-electric film.

A piezo-electric resonator capable of advantageously being made small in size is used in a duplexer for separating a transmission signal and a reception signal, for example, in a portable wireless communication apparatus.

In the duplexer using a conventional piezo-electric resonator, a transmission side filter and a reception side filter are made into respective packages. The respective packages are contained in a package for an electric circuit substrate to form the duplexer. With this structure, the above-mentioned advantages of small size cannot be sufficiently obtained in the duplexer. As a result, the duplexer inevitably becomes large in size.

Under the circumstances, for the purpose of making the duplexer small in size, it can be considered that the piezo-electric resonator is mounted on a packaging substrate by a face-down bonding of a flip-chip using bumps (electrically connected projecting portion) in spite of a wire-bonding. By the flip-chip bonding, since a chip of the piezo-electric resonator can be electrically connected to the packaging substrate within an area of the chip, a two-dimensional space on the packaging substrate can be used efficiently. In addition, the duplexer can be made small in height, because the flip-chip bonding uses no wire that forms a loop and therefore needs a height to some extent.

Herein, a technique that the piezo-electric resonator is mounted on the packaging substrate by the flip-chip bonding is exemplified in, for example, Japanese laid open Official Gazettes No. 2002-232253, No. Hei 10-270979, respectively. Further, a technique that two piezo-electric resonators are mounted on the packaging substrate by the flip-chip bonding to form a duplexer is exemplified in, for example, Japanese laid open Official Gazettes No. Hei 11-88111, No. 2003-179518, respectively.

However, in the above-mentioned techniques, no consideration is made about reliability in mounting, such as precision of positioning in the face-down bonding and the like, or about reliability in operation, such as changes of frequency characteristics and the like.

In addition, it is necessary to consider further possibility of making the duplexer smaller in size.

### SUMMARY OF THE INVENTION

It is an object of the present invention to provide a technique capable of improving reliability in an electronic component in which the piezo-electric resonator is mounted on the packaging substrate by the face-down bonding.

It is another object of the present invention to provide a technique capable of rendering a compact electronic component smaller in size.

Other objects of the present invention will become clear as the description proceeds.

According to an aspect of the present invention, there is provided an electronic component, comprising: a piezo-electric resonator which is formed on an element substrate and which has a piezo-electric film, the piezo-electric resonator obtaining a signal having a predetermined resonant frequency by a bulk wave propagating through the piezo-electric film; a packaging substrate on which the piezo-electric resonator is mounted by a face-down bonding through an electrically connected projecting portion; a sealing member which is fixed on the packaging substrate and which seals the piezo-electric resonator; and a distance between a surface of the piezo-electric resonator facing the packaging substrate and a surface of the packaging substrate facing the piezo-electric resonator being not larger than 100 μm.

According to another aspect of the present invention, there is provided an electronic component, comprising: a piezo-electric resonator which is formed on an element substrate and which has a piezo-electric film, the piezo-electric resonator obtaining a signal having a predetermined resonant frequency by a bulk wave propagating through the piezo-electric film; a packaging substrate on which the piezo-electric resonator is mounted by a face-down bonding through an electrically connected projecting portion; a sealing member which is fixed on the packaging substrate and which seals the piezo-electric resonator; and a maximum diameter of the electrically connected projecting portion being not larger than 150 μm when the electrically connected projecting portion is connected to the packaging substrate.

The number of the electrically connected projecting portion formed on the piezo-electric resonator may be eight.

According to yet another aspect of the present invention, there is provided an electronic component, comprising: a piezo-electric resonator which is formed on an element substrate and which has a piezo-electric film, the piezo-electric resonator obtaining a signal having a predetermined resonant frequency by a bulk wave propagating through the piezo-electric film; a packaging substrate on which the piezo-electric resonator is mounted by a face-down bonding through an electrically connected projecting portion; a sealing member which is fixed on the packaging substrate and which seals the piezo-electric resonator; and a distance between a surface of the piezo-electric resonator facing the sealing member and a surface of the sealing member facing the piezo-electric resonator being not larger than 150 μm.

The surface of the piezo-electric resonator facing the sealing member and the surface of the sealing member facing the piezo-electric resonator may be coupled with each other.

A buffer may be located for burying a space between the piezo-electric resonator and the packaging substrate.

A buffer may be located for burying a space between the piezo-electric resonator and the sealing member.

The buffer may be an adhesive for fixing the piezo-electric resonator and the sealing member.

The electrically connected projecting portion may be formed by gold.

A couple of the piezo-electric resonators may be mounted on the packaging substrate, one may be a transmission side filter for processing a transmission signal while another may be a reception side filter for processing a reception signal.

The piezo-electric resonator may be an SMR type piezo-electric resonator.

### BRIEF DESCRIPTION OF THE DRAWINGS

FIG. 1 is a sectional view for schematically showing a piezo-electric resonator used in an electronic component according to a first embodiment of the present invention;

FIG. 2 is a sectional view for schematically showing the electronic component according to the first embodiment of the present invention; and

FIG. 3 is a sectional view for schematically showing an electronic component according to a second embodiment of the present invention.

### DETAILED DESCRIPTION OF THE PREFERRED EMBODIMENTS

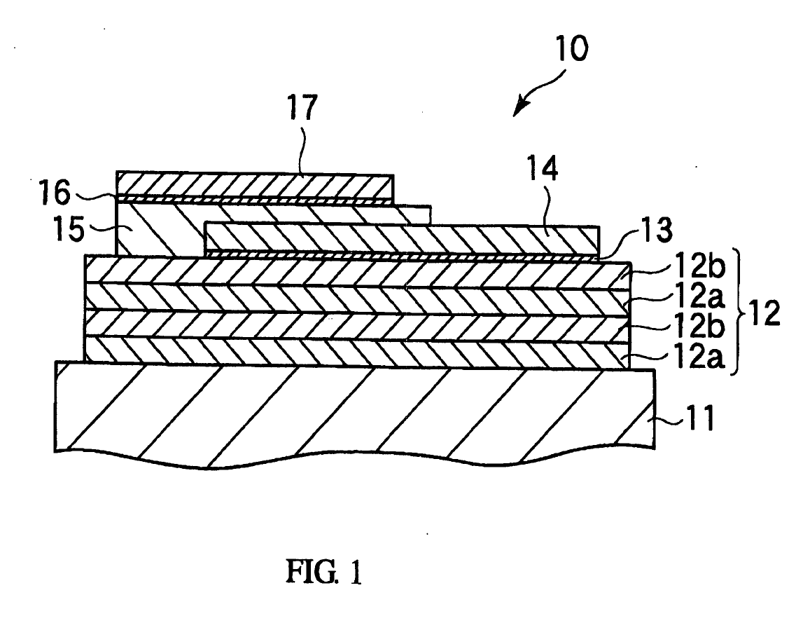

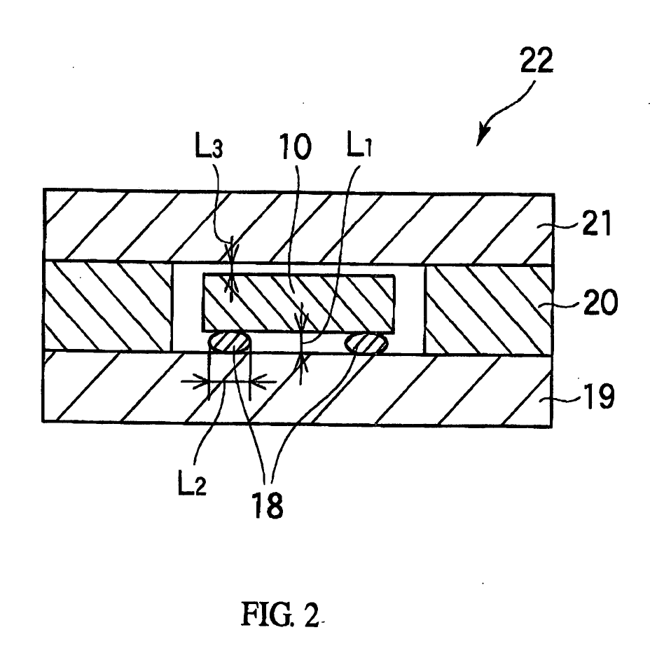

Now, referring to FIGS. 1 and 2, description will proceed to an electronic component according to a first embodiment of the present invention. FIG. 1 is a sectional view for showing a piezo-electric resonator used in the electronic component according to the first embodiment of the present invention. FIG. 2 is a sectional view for showing the electronic component illustrated in FIG. 1.

A piezo-electric resonator 10 illustrated in FIG. 1 is such a piezo-electric resonator that is called “SMR (Solidly Mounted Resonator) type piezo-electric resonators”. In the piezo-electric resonator 10, an acoustic reflection film 12 composed of two thin films each having high acoustic impedance, for example, AlN films 12a and two thin films each having low acoustic impedance, for example, SiO2 films 12b is formed on an element substrate 11 consisting substantially of, for example, single crystal silicon with the respective four thin films being stacked alternately. A Pt film is deposited on the acoustic reflection film 12 by a vacuum deposition method through an AlN film as an adhesion layer 13. The Pt film is subjected to patterning by lithography to form a lower electrode 14.

Further, a piezo-electric film 15 of ZnO is deposited on the lower electrode 14 by a sputtering method. An Al film is deposited on the piezo-electric film 15 also by the sputtering method through a Cr film as an adhesion layer 16. The Al film is subjected to patterning by lithography to form an upper electrode 17. Besides, a thickness of the piezo-electric film 15 is generally not larger than 10 μm. It is therefore difficult to make the piezo-electric resonator 10 without using the element substrate 11. Further, a hole or holes can be formed on the piezo-electric film 15 by etching or the like so that the lower electrode 14 may be exposed.

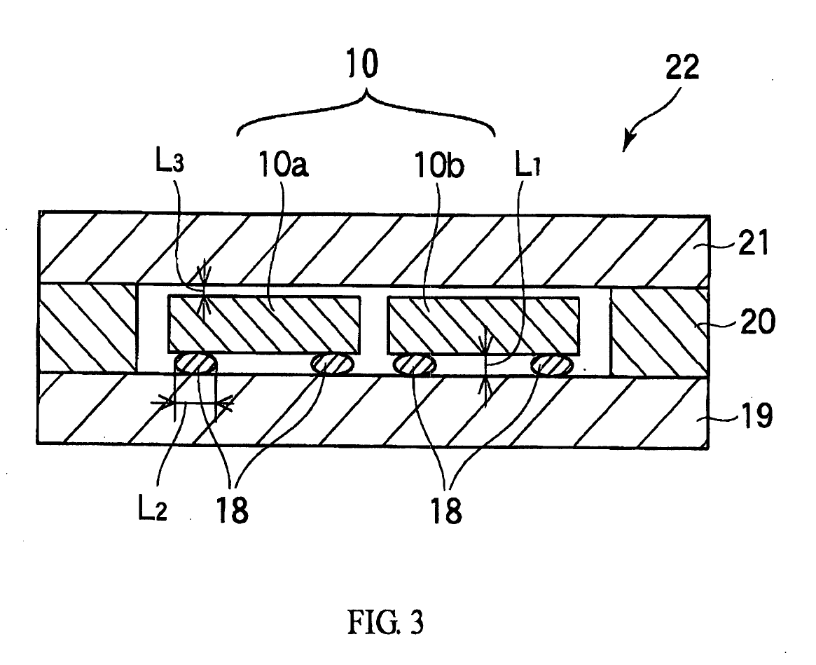

In the piezo-electric resonator 10 thus mentioned, bumps (electrically connected projecting portions) 18, such as stud bumps, plating bumps and the like are formed on the lower electrode 14 and the upper electrode 17, as illustrated in FIGS. 2 and 3. Accordingly, let the piezo-electric resonator 10 be mounted on a packaging substrate 19 described later and then let alternating voltage be applied on the lower electrode 14 and the upper electrode 17. Consequently, a bulk wave propagates through the piezo-electric film 15 by piezo-electric effect and thereby a signal having a predetermined resonant frequency can be obtained.

Besides, the acoustic reflection film 12 may not be formed. In this case, the lower electrode 14 is formed directly on the element substrate 11. Further, the acoustic reflection film 12 is composed of four layers in this embodiment. The number of the layers of the acoustic reflection film 12 is not restricted to four. The acoustic reflection film 12 may be composed of any other number of thin films, when the thin films having acoustic impedances different from each other are stacked alternately. Further, a material of each thin film is not restricted to the above-mentioned one. The above-mentioned material is merely one example thereof. Further, solder, gold, aluminum, copper and the like can be applied to the bumps 18.

However, in a case that the solder is applied to the bumps 18, fluxes are likely to be scattered on a surface of the piezo-electric resonator 10 during solder heating and melting process. Further, in the case, impurities, such as melted flux of washing solution and the like are likely to remain after washing process. On the contrary, in a case that the gold is applied to the bumps 18, there is no fear of scattered fluxes and remaining impurities. It is therefore desirable that the bumps 18 are formed by gold.

As illustrated in FIGS. 2 and 3, the piezo-electric resonator 10 is mounted on the packaging substrate 19 through the bumps 18 by the face-down bonding. An annular spacer 20 is fixed in a peripheral portion of the packaging substrate 19. A lid (sealing member) 21 is fixed on the annular spacer 20, so that the piezo-electric resonator 10 is sealed to form an electronic component 22.

Besides, in the illustrated example, the packaging substrate 19 and the lid 21 are fixed each other through the annular spacer 20. Alternatively, the packaging substrate 19 and the lid 21 may be directly fixed each other. This is achieved, for example, by making a wall of the peripheral portion of the packaging substrate 19, or by rendering the lid 21 to have a cap-like shape.

In the electronic component 22 illustrated in FIG. 2, one piezo-electric resonator 10 is mounted to form a filter. On the other hand, in the electronic component 22 illustrated in FIG. 3, two piezo-electric resonators 10 are mounted. One of the two piezo-electric resonators 10 forms a transmission side filter 10a for processing a transmission signal while another one thereof forms a reception side filter 10b for processing a reception signal. In the present invention, one or a plurality of piezo-electric resonators 10 can be thus mounted on the packaging substrate 19.

Herein, although only two bumps 18 are shown in FIGS. 2 and 3 per each piezo-electric resonator 10, the piezo-electric resonator 10 is mounted on the packaging substrate 19 by the face-down bonding through eight bumps to make the electronic component 22 in this embodiment.

At first, in the electronic component 22 thus mentioned, investigation was made about a distance L₁ (illustrated in FIGS. 2 and 3) between a surface of the piezo-electric resonator 10 facing the packaging substrate 19 and a surface of the packaging substrate 19 facing the piezo-electric resonator 10. Namely, the distance L₁ is such a distance between a lower surface of the piezo-electric resonator 10 and an upper surface of the packaging substrate 19 in the sheets of FIGS. 2 and 3.

As a result, when the distance L₁ is 130 μm, junction positions of the bumps 18 in the packaging substrate 19 have largely swerved from predetermined positions by ±15 μm. Accordingly, it becomes necessary to make a size of an electrode to be junctioned in the packaging substrate 19, 150×150 μm². On the other hand, when the distance L₁ is 100 μm, the junction positions of the bumps 18 in the packaging substrate 19 have swerved from the predetermined positions only by ±7 μm. Accordingly, the size of the electrode to be junctioned in the packaging substrate 19 can be 120×120 μm², which is smaller than the above size of 150×150 μm². Besides, when the distance L₁ is 50 μm, the junction positions of the bumps 18 in the packaging substrate 19 have swerved from the predetermined positions only by ±5 μm. Subsequently, the size of the electrode to be junctioned in the packaging substrate 19 is 115×115 μm². Further, when the distance L₁ is 25 μm, the junction positions of the bumps 18 in the packaging substrate 19 have swerved from the predetermined positions only by ±3 μm. Subsequently, the size of the electrode to be junctioned in the packaging substrate 19 is 110×110 μm².

When the distance L₁ becomes larger, height of the bumps 18 also becomes larger. It is necessary that a plurality of the bumps 18 are stacked for the purpose of making the height of the bumps 18 become larger. In a case that a plurality of the bumps 18 are thus stacked, the stacked bumps 18 swerve inevitably from each other. As a result, it becomes difficult that the stacked bumps 18 stand vertically. Subsequently, when the piezo-electric resonator 10 having a plurality of such bumps 18 is mounetd on the packaging substrate 19 by the face-down bonding, the positions of respective bumps 18 in the packaging substrate 19 are likely to swerve from respective predetermined positions. Under the circumstances, in view of a relation between the distance L₁ and a swerve of the position, the distance L₁ is determined to be not larger than 100 μm, preferably not larger than 50 μm, and more preferably not larger than 25 μm. Accordingly, precision of positioning becomes better in the face-down bonding. Thereby, reliability of mounting can be improved in the face-down bonding.

Next, further investigation was made as regards a maximum diameter L₂ after the bumps 18 formed on the piezo-electric resonator 10 have been junctioned on the packaging substrate 19.

Herein, when the maximum diameter L₂ is 170 μm, a pad having an area of 190×190 μm² is located on the piezo-electric resonator 10 with respect to one bump 18. Subsequently, in order to form the eight bumps 18, eight pads each having the area of 190×190 μm² are located on the piezo-electric resonator 10. As a result, the piezo-electric resonator 10 has come to have a size of 1×1.8 mm² including a portion of a filter. Further, if a diameter of the bump 18 is large, not only a load forced on the bump 18 at the time of junction but also an output of an ultrasonic wave become large. Consequently, cracks are sometimes generated in an element substrate 11 on which the bumps 18 are formed in the piezo-electric resonator 10. In a case that the maximum diameter L₂ is 170 μm, as mentioned above, in thirty percentages of the piezo-electric resonators 10 and with respect to at least one bump 18 among the eight bumps 18, a crack was generated in a portion of the element substrate 11 on which the one bump 18 is located.

On the other hand, when the maximum diameter L₂ is 150 μm, a pad having an area of 165×165 μm² is located on the piezo-electric resonator 10 with respect to one bump 18. Subsequently, in order to form the eight bumps 18, eight pads each having the area of 165×165 μm² are located on the piezo-electric resonator 10. As a result, the piezo-electric resonator 10 has come to have a size of 1×1.7 mm² including a portion of a filter. Further, when the maximum diameter L₂ is 100 μm, a pad having an area of 115×115 μm² is located on the piezo-electric resonator 10 with respect to one bump 18. Subsequently, in order to form the eight bumps 18, eight pads each having the area of 115×115 μm² are located on the piezo-electric resonator 10. As a result, the piezo-electric resonator 10 has come to have a size of 1×1.55 mm² including a portion of a filter. Consequently, in a case that the maximum diameter L₂ is 150 μm, only in approximately three percentages of the piezo-electric resonators 10, a crack was generated in a portion of the element substrate 11 on which the one bump 18 is located. On the other hand, in a case that the maximum diameter L₂ is 100 μm, in none of the piezo-electric resonators 10, a crack was generated in a portion of the element substrate 11 on which the one bump 18 is located.

Under the circumstances, it is, of course, desirable that the piezo-electric resonator 10 is made small in size. As regards the maximum diameter L₂ and a size of the piezo-electric resonator 10, from the view point of an area efficiency and a possibility of generation of the cracks, it is preferable that the maximum diameter L₂ is not larger than 150 μm. It is more preferable that the maximum diameter L₂ is not larger than 100 μm. The value of the maximum diameter L₂ is particularly preferable, in a case that the number of the bumps 18 is eight.

Besides, for example, in a case that the bump 18 consisting of gold is used, ultrasonic waves are applied on the bump 18 in one direction thereof during junction of the bump 18. As a result, a shape of the plan view of the bump 18 after the junction is an oval shape or an elliptic shape. Herein, the largest value of the oval shape or the elliptic shape is defined as the maximum diameter L₂.

At last, an investigation was made as regards a distance L₃ (illustrated in FIGS. 2 and 3) between a surface of the piezo-electric resonator 10 facing the lid 21 and a surface of the lid 21 facing the piezo-electric resonator 10. Namely, the distance L₃ is such a distance between an upper surface of the piezo-electric resonator 10 and a lower surface of the lid 21 in the sheets of FIGS. 2 and 3. Besides, the lid 21 is kept at a ground voltage by a castration (a conducive member by making a groove at the side surface of the package and forming a conductive material therein) positioned at the side surface of the package.

As a result, when the distance L₃ is 200 μm, a center frequency of the piezo-electric resonator 10 is varied depending on a situation of ground of the lid 21 and the like. Accordingly, an electric characteristic of the filter became unstable. On the other hand, when the distance L₃ is 150 μm, the center frequency of the piezo-electric resonator 10 was only varied by approximately 0.1 percentage among approximately five percentages of the piezo-electric resonators 10. Namely, for example, in a case that the center frequency is 2 GHz, the center frequency was varied by 1 through 2 MHz. Subsequently, almost no problem is caused to occur. Further, when the distance L₃ is 100 μm, the center frequency of the piezo-electric resonator 10 was not varied at all. Accordingly, it is preferable that the distance L₃ is not larger than 150 μm. It is more preferable that the distance L₃ is not larger than 100 μm.

Herein, a buffer (not shown in FIGS. 2 and 3) may be located for burying a space between the surface of the piezo-electric resonator 10 facing the lid 21 and the surface of the lid 21 facing the piezo-electric resonator 10. Alternatively, the surface of the piezo-electric resonator 10 facing the lid 21 may be junctioned with the surface of the lid 21 facing the piezo-electric resonator 10. With the structures thus mentioned, the piezo-electric resonator 10 comes to be pressed by the packaging substrate 19. A reliability of mounting the piezo-electric resonator 10 is thereby improved. Besides, an adhesive for firing the piezo-electric resonator 10 and the lid 21 can be used as the buffer. In this case, the reliability of mounting the piezo-electric resonator 10 is further improved. It is not restricted that the buffer is inserted between the surface of the piezo-electric resonator 10 facing the lid 21 and the surface of the lid 21 facing the piezo-electric resonator 10. The buffer can be inserted between the piezo-electric resonator 10 and the annular spacer 20. The buffer can also be inserted between a surface of the piezo-electric resonator 10 facing the packaging substrate 19 and a surface of the packaging substrate 19 facing the piezo-electric resonator 10. Thereby, similar meritorious effect can be obtained.

While this invention has thus far been described in specific conjunction with several embodiments thereof, it will now be readily possible for one skilled in the art to put this invention into effect in various other manners.

For example, the above description was made about a case that the present invention is applied to the, SMR type piezo-electric resonator. The present invention can be applied to all of a stacked-type piezo-electric resonator using a piezo-electric film, such as a diaphragm type piezo-electric resonator in which acoustic total reflection is carried out by opening a piezo-electric film interposed between upper and lower electrodes to the air in the upper and the lower directions thereof, a space-type piezo-electric resonator and the like.

1. An electronic component, comprising:
a piezo-electric resonator which is formed on an element substrate and which has a piezo-electric film, said piezo-electric resonator obtaining a signal having a predetermined resonant frequency by a bulk wave propagating through said piezo-electric film;
a packaging substrate on which said piezo-electric resonator is mounted by a face-down bonding through an electrically connected projecting portion;
a sealing member which is fixed on said packaging substrate and which seals said piezo-electric resonator; and
a distance between a surface of said piezo-electric resonator facing said packaging substrate and a surface of said packaging substrate facing said piezo-electric resonator being not larger than 100 μm.

2. An electronic component, comprising:
a piezo-electric resonator which is formed on an element substrate and which has a piezo-electric film, said piezo-electric resonator obtaining a signal having a predetermined resonant frequency by a bulk wave propagating through said piezo-electric film;
a packaging substrate on which said piezo-electric resonator is mounted by a face-down bonding through an electrically connected projecting portion;
a sealing member which is fixed on said packaging substrate and which seals said piezo-electric resonator; and
a maximum diameter of said electrically connected projecting portion being not larger than 150 μm when said electrically connected projecting portion is connected to said packaging substrate.

3. An electronic component as claimed in claim 2, wherein the number of said electrically connected projecting portion formed on said piezo-electric resonator is eight.

4. An electronic component, comprising:
a piezo-electric resonator which is formed on an element substrate and which has a piezo-electric film, said piezo-electric resonator obtaining a signal having a predetermined resonant frequency by a bulk wave propagating through said piezo-electric film;
a packaging substrate on which said piezo-electric resonator is mounted by a face-down bonding through an electrically connected projecting portion;
a sealing member which is fixed on said packaging substrate and which seals said piezo-electric resonator; and
a distance between a surface of said piezo-electric resonator facing said sealing member and a surface of said sealing member facing said piezo-electric resonator being not larger than 150 μm.

5. An electronic component as claimed in claim 4, wherein said surface of said piezo-electric resonator facing said sealing member and said surface of said sealing member facing said piezo-electric resonator are coupled with each other.

6. An electronic component as claimed in claim 4, wherein a buffer is located for burying a space between said piezo-electric resonator and said packaging substrate.

7. An electronic component as claimed in claim 4, wherein a buffer is located for burying a space between said piezo-electric resonator and said sealing member.

8. An electronic component as claimed in claim 7, wherein said buffer is an adhesive for fixing said piezo-electric resonator and said sealing member.

9. An electronic component as claimed in claim 1, wherein said electrically connected projecting portion is formed by gold.

10. An electronic component as claimed in claim 1, wherein a couple of said piezo-electric resonators are mounted on said packaging substrate, one being a transmission side filter for processing a transmission signal while another being a reception side filter for processing a reception signal.

11. An electronic component as claimed in claim 1, wherein said piezo-electric resonator is an SMR type piezo-electric resonator.
